(19) United States
(12) Patent Application Publication
(10) Pub. No.: US 2025/0233510 A1
(43) Pub. Date: Jul. 17, 2025

(54) INTEGRATED POWER BLOCK

(71) Applicant: Moksha Integrated Power LLC, Oceanside, CA (US)

(72) Inventors: Sharad Sundar, Oceanside, CA (US); Arun Sundar, Oceanside, CA (US); Rajagopalan Sundar, Oceanside, CA (US)

(73) Assignee: Moksha Integrated Power LLC, Oceanside, CA (US)

(21) Appl. No.: 18/730,776

(22) PCT Filed: Jan. 31, 2023
(86) PCT No.: PCT/US2023/012006

§ 371 Date: Jul. 21, 2024

(51) Int. Cl. H02M 1/10; H02M 1/00; H02M 1/42; H02M 3/335

(52) U.S. Cl. CPC H02M 1/10; H02M 1/0012; H02M 3/33573; H02M 3/33584; H02M 1/4208

(57) ABSTRACT

A digital power conversion system is described with a control system, power system, DC bus system, and AC bus system housed in a case. The user-programmable control system outputs pulse-width modulated (PWM) signals and input/output (I/O) signals. The power system uses these PWM signals to drive integrated power transistors to achieve a variety of power conversion functions. The DC bus system includes positive and negative DC buses accessible via positive and negative DC terminals and is connected to the power system, while the AC bus system comprises AC buses accessible via AC terminals and is also connected to the power system. The system provides an efficient and integrated power electronics platform at its rated ranges by harnessing digital power conversion and other techniques.

### TECHNICAL FIELD

This invention relates to a novel integrated power conversion system and related modules. Specifically, this invention is a self-contained digital high voltage power electronics module and its various embodiments, capable of a plurality of functions directly related to electrical and electronic power conversion.

### BACKGROUND ART

The present State of Art, relating to the design and manufacture of electrical/electronic power conversion comprising the 100 Watt to 20 kilowatt range, is technically complex-requiring specialized skills in the Art to convert electrical power from AC to DC, DC to DC, DC to AC, and AC to AC safely and efficiently, while serving the unique needs of a specific power conversion system.

### SUMMARY OF INVENTION

### Technical Problem

The power electronics industry today struggles to design power conversion solutions with discrete complex subsystems in the 100 Watt to 20 kilowatt range, partially due to the inevitable technical complexity of conventional power solutions. The critical facets of conventional solutions vary in manufacture and execution, but typically include Power Switching, Gate Control, Feedback, Isolation (if needed), and Protection elements. These elements must work in unison to perform their function of Power Conversion, and each element can demand its own field of technical expertise.

The industry of power electronics suffers a process which hampers rapid innovation in the evolving power supply, robotics, and electrification markets, among others, whose quintessence is the need to innovate rapidly. Typically, complex power conversion elements are built from individual electronic components, with a complete power solution in the 100 W-20 kW range having near 200 to 400 discrete electronic parts. Each component requires a designated footprint on a custom manufactured circuit board.

Designing a custom power solution generally necessitates painstaking cycles of custom design over a broad range of design disciplines. A cycle such as this may demand multiple design professionals each well-versed in their specific mastery of the art, the sourcing and logistical process resulting from board redesign and component reacquisition in a shifting supply landscape, and other historic and contemporary factors which in total lead to a substantial increase of development cost and time burden when designing a solution. Such a custom design cycle can require the dedication of several weeks to several months depending on the complexity of performance specifications. Even to one skilled in the art, high-voltage power conversion can be a prohibitively difficult process which can discourage innovation and punish early adoption of breakthrough technologies.

Another major challenge for present day power conversion solutions is minimizing the form factor, typically due to the large number of discrete components needed to customize a power solution to meet the required specifications. These factors and others add to the cost of logistics, proving detrimental in various ways to the productization and market appeal of a power solution.

### Solution to Problem

It is apparent that a need exists for an invention which integrates as many critical and discrete core components of power conversion as possible into a single hardware component, offering ready-to-use functional power conversion ‘blocks’ as integrated single components and obviating the need for case by case development effort wherever possible.

The art of digital power conversion provides an ideal environment for the development of such an invention. The use of a signal processing microcontroller can offer improved performance compared to analog circuits, including higher accuracy, stability, and flexibility. Digital circuits can be easily scaled to handle complex power conversion systems, and can provide improved monitoring and control capabilities to enable real-time analysis and optimization of a system.

A signal processing circuit comprising a microcontroller is capable of controlling the common Gate Control elements of a wide range of power conversion solutions without hardware reconfiguration. By additionally integrating the appropriate semiconductor transistors, the Power Switching elements can also be made common over a wide range of power ratings. While the Feedback, Protection, and Isolation elements of a solution are typically unique to a specific system's performance requirements, the Power Switching and Gate Control components could be configured to span multiple topologies, and might in this way be common to multiple solutions currently in use by the industry.

In various embodiments, a system for digital power conversion designated the Integrated Power Block (IPB) is disclosed. The IPB saves a large fraction of the stated development cost and time burden currently present in the power electronics industry, and can provide its user with an additional plurality of functions not limited to those directly related to electrical and electronic power conversion. The IPB includes, and is not limited to, further embodiments, each with its own device arrangements, or configurations, to serve a wide range of power conversion topologies for converting AC to DC, DC to DC, DC to AC, and/or AC to AC, across a wide range of power requirements.

### Advantageous Effects of Invention

The IPB can be readily programmed to implement any of a multiplicity of power conversion functions. The majority of the current industry's power conversion solutions require two or more of such functions to be implemented to meet required performance specifications, a single hardware block or a plurality of the same hardware block can be used, each with its own specific programming, to achieve the different desirable power conversion functions of a given system. The invention enables the availability of a single sealed hardware component, obviating the need for laborious engineering and integration of a solution's individual functional elements in the cases where an IPB would be applicable.

Digital power conversion uniquely allows unprecedented access to model-predictive control strategies. To facilitate this, the structure of the IPB makes a plethora of uncommitted analog and digital ports accessible to the end user, providing access to a vast array of additional intelligent control and monitoring functions which can be programmed into the invention. Examples of such functions include the calculation of electrical parameters such as power factor, energy usage, energy cost, power delivery, and harmonics. Further applications may include parallel operation of blocks for the purpose of increased power throughput, temperature monitoring and control, and “N+1” redundant operation.

The IPB is also capable of bidirectional communication with the external world, configurable for most of the communication protocols prevalent in the automotive, industrial control and automation, and communication industries, including but not limited to PMBus, 12C, CAN, SPI, SCI, LIN, and FSI. The advantage of access by already-established protocols can further enable fast adoption and promote standard usage of digital power conversion in the affected industries.

### BRIEF DESCRIPTION OF THE DRAWINGS

Other features, combinations, and embodiments will be appreciated by one having the ordinary level of skill in the art of antennas and accessories upon a thorough review of the following details and descriptions, particularly when reviewed in conjunction with the drawings, wherein:

FIG. 1 shows a schematic block diagram illustrating a Full Bridge IPB, in accordance with the first embodiment;

FIG. 2 shows a schematic block diagram illustrating a Half Bridge IPB, in accordance with a second illustrated embodiment;

FIG. 3 shows a schematic block diagram illustrating a Three Phase IPB, in accordance with a third illustrated embodiment;

FIG. 4 shows a schematic block diagram illustrating a Three Phase+Half Bridge IPB, in accordance with a fourth illustrated embodiment;

FIG. 5 shows a schematic block diagram illustrating a Dual Half Bridge IPB, in accordance with a fifth illustrated embodiment;

FIG. 6 shows a schematic block diagram illustrating a Dual Full Bridge IPB, in accordance with a sixth illustrated embodiment;

FIG. 7 shows a block diagram illustrating a fully functional power conversion solution—a Bidirectional PFC/Inverter topology, which can use the Full Bridge IPB in accordance with the first embodiment. A perspective of a Full Bridge IPB is shown;

FIG. 8 shows a block diagram illustrating a fully functional power conversion solution—a Dual Active Bridge topology, which can use a Dual Full Bridge IPB in accordance with the sixth embodiment. A perspective of a Dual Full Bridge IPB is shown; and

FIG. 9 shows a front and side perspective view of a Full Bridge IPB, in accordance with the first embodiment.

### DETAILED DESCRIPTION

For purposes of explanation and not limitation, details and descriptions of certain preferred embodiments are hereinafter provided such that one having ordinary skill in the art may be enabled to make and use the invention. These details and descriptions are representative only of certain preferred embodiments, however, a myriad of other embodiments which will not be expressly described will be readily understood by one having skill in the art upon a thorough review of the instant disclosure. Accordingly, any reviewer of the instant disclosure should interpret the scope of the invention only by the claims, as such scope is not intended to be limited by the embodiments described and illustrated herein.

For purposes herein, the term “FET” means semiconductor transistors.

The term “DSP” means digital signal processing

The term “PWM” means pulse-width modulation.

The term “HDC” means high density connector.

The term “IGD” means isolated gate driver circuit.

The term “LP” means logic power circuit.

The term “FSL” means power failsafe circuit.

The term “UI” means user interface.

The term “CI” means communication interface.

The term “LF FET” means low frequency switching device circuits.

Unless explicitly defined herein, terms are to be construed in accordance with the plain and ordinary meaning as would be appreciated by one having skill in the art.

### General Description of Embodiments

In an embodiment, a system for digital power conversion is disclosed. The system comprises a case comprising an insulating outer shell and an insulating internal material, a control system housed in the case wherein the control system is configured by a software framework to output pulse-width modulated (PWM) signals and input/output (I/O) signals, a power system housed in the case wherein the power system is configured to receive and operate in accordance with the PWM signals, a DC bus system housed in the case and electrically coupled to the power system wherein the DC bus system comprises one or more DC buses, each individually comprising a positive DC bus and a negative DC bus, and wherein the positive DC bus and the negative DC bus of each of the one or more DC buses are each externally accessible via a corresponding pair of DC terminals comprising a positive DC terminal and a negative DC terminal, and an AC bus system housed in the case and electrically coupled to the power system, wherein the AC bus system comprises one or more AC buses and wherein each of the one or more AC buses is externally accessible via an AC terminal.

In some embodiments, the case may further comprise a conductive internal lining disposed between the insulating outer shell and the insulating internal material, configured to act as a Faraday cage.

In some embodiments, the control system may comprise a digital signal processing subsystem comprising one or more digital signal processing circuits, wherein the digital signal processing subsystem is configured to generate and transmit the PWM signals and the I/O signals, the I/O signals comprise serial/communication I/O signals, and wherein the control system further comprises an externally accessible high density connector electrically coupled to at least one of the I/O signals.

In some embodiments, the control system may further comprise a communication interface subsystem and one or more externally accessible user interface connectors, the communication interface subsystem comprises a signal isolator, and wherein the communication interface subsystem electrically couples the serial/communication I/O signals to the one or more externally accessible user interface connectors.

In some embodiments, the power system may comprise a logic power subsystem comprising one or more logic power circuits electrically coupled to the DC bus system, a power failsafe subsystem electrically coupled to the logic power subsystem and comprising sensing elements, a gate driver subsystem comprising one or more gate driver circuits each gate driver circuit being electrically coupled to the power failsafe subsystem and to the PWM signals, and a switching device subsystem comprising one or more semiconductor transistor circuit, each semiconductor transistor circuit being electrically coupled to the gate driver subsystem, and the switching device subsystem being electrically coupled to the DC bus system or the AC bus system.

In some embodiments, the power system may further comprise an insulated metal substrate layer bonded to the power system, and wherein the insulated metal substrate layer is externally accessible and is thermally coupled to at least one of the one or more semiconductor transistors.

The IPB as disclosed herein is preferably a system which compresses the most ubiquitous components of digital power conversion into a single, portable component, forming a universal hardware platform for power conversion within the IPB's specified power and voltage rating, given the correct software configuration for each intended use. As such, the IPB's best mode of embodiment is to minimize form factor while safely providing I/O and UI connections to the user in the format most easily accessible to the desired application, in the effort to be universally applicable within the range of power conversion tasks corresponding to the specified rating.

The IPB preferably aids the designer and the user against the common problems of power electronics design, not limited to those of part complexity and electrical/thermal efficiency, while maintaining a simple structure that comprises or integrates easily with any Power Switching, Gate Control, Feedback, Isolation, or Protection elements necessary for any application within the target range.

Advances in microprocessing technology and reference design library quality have bestowed modern signal processing microcontrollers with a very long list of capabilities for which ample reference documentation typically exists. As examples, some of the capabilities of the DSP are described:

Switching Topologies: The DSP can be programmed to configure the power switches in any of multiple modes of operation, by generating the required high frequency PWM signals simultaneously for all the power devices. For example, the two half bridges can be programmed to operate exactly in parallel and in sync with each other, to deliver twice the output current (hence twice the power) of the individual half bridge. A popular variation is to “interleave” the output of the two half bridges to reduce the high frequency ripple by half, yet deliver twice the rated output of each half bridge, and this can be readily achieved through simple programming techniques using the DSP. Another popular configuration is to operate the two half bridges in a “full bridge” mode whereby the two half bridges complement each other's output voltage, which can be readily used to drive a high frequency transformer, for example. Yet another configuration of the power switches involves operating one pair at high switching frequency, but the second pair at the low Utility frequency (such as 60 Hz, or 50 Hz, or 400 Hz). This configuration not only eliminates the need for a diode bridge (thus eliminate the added power loss) enabling the popular Bridgeless Totem Pole configuration, but also using the same set of hardware to convert power in either direction (from AC to DC, or from DC to AC), with only change in commands to the DSP. For example, the Integrated Power Block (together with a simple set of feedback circuits and passive bulk components) can be configured to perform an AC to DC charger function, and the same set of hardware combination with no changes can be programmed to perform the DC to AC inverter function. The operational combinations and topologies are numerous, limited primarily by the skill and ingenuity of the programming and design team.

Computation: The DSP is a very powerful and sophisticated mathematical engine, capable of high throughput of calculations, and also capable of highly complex mathematics. For example, the DSP can be programmed to monitor and report instantaneous power, aggregate energy (over any specified time period), power efficiency, energy loss, cost savings, etc. It can also be programmed to measure waveform harmonics, Bode Plots of the current and voltage control loops, compensation for these loops, and ensure stable and dependable operation of these loops and hence the entire power conversion system, under transient as well as steady state conditions. Dedicated Serial Communication interface can be readily used for these purposes.

Communication: The DSP is a versatile communication engine, and can be programmed to communicate with many popular communication protocols such as CAN, PMBus, SPI, I2C, LIN, FSI, etc. It also has a dedicated Serial Communication interface (mentioned above), along with a dedicated JTAG interface for programming the device.

System Implementation: The DSP is ideally suited to configure the Integrated Power Block to either operate stand alone, or operate in parallel with other Blocks, to deliver correspondingly increased power. It can also be programmed for “N+1” redundancy, whereby failure of one Block would allow the continued operation of the other blocks, which is highly sought after for mission critical applications.

Each of the components of the disclosed invention and related system described herein may be manufactured and/or assembled in accordance with the conventional knowledge and level of a person having skill in the art.

While various details, features, combinations are described in the illustrated embodiments, one having skill in the art will appreciate a myriad of possible alternative combinations and arrangements of the features disclosed herein. As such, the descriptions are intended to be enabling only, and non-limiting. Instead, the spirit and scope of the invention is set forth in the appended claims.

### Illustrated Embodiments

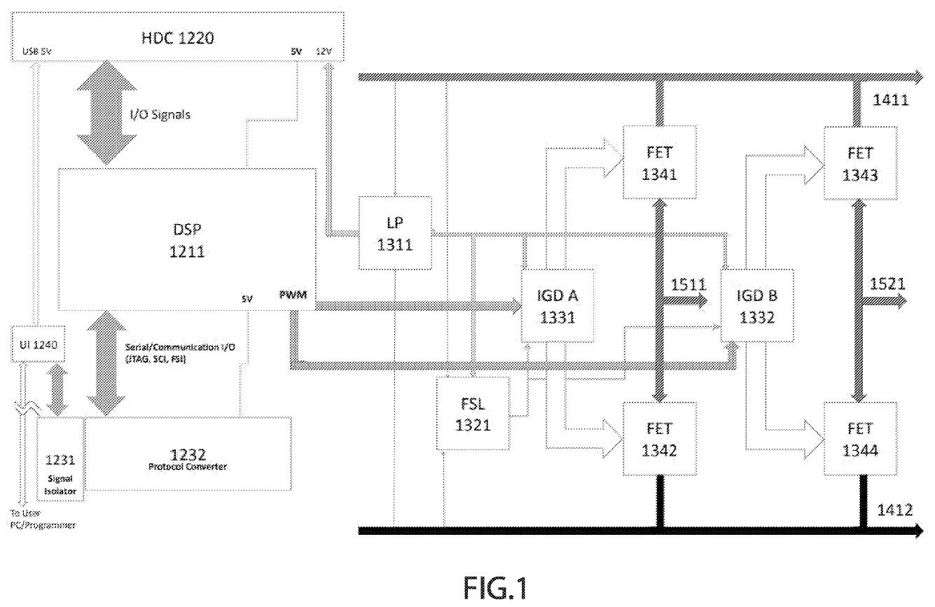

Now turning to the drawings, FIG. 1 shows a schematic block of a Full Bridge IPB according to the first illustrated embodiment. The IPB comprises functional elements as a single sealed hardware block including a case (1100), a power system (1300), a control system (1200), a DC Bus (1410), and two AC buses (1510; 1520). The case (1100) includes an outer shell and internal material. The power system (1300) comprises four high frequency, high power semiconductor transistors (1341; 1342; 1343; 1344), two gate driver circuits (1331;1332), a logic power circuit (1311), a power failsafe circuit (1321), and an insulated metal substrate layer (1350).

The control system (1200) comprises a digital signal processing circuit (1211), a communication interface (1230) with integrated signal isolator (1231) and protocol converter circuit (1232), a user interface connector (1240), and a high-density connector (1220). The DC bus (1410) comprises a positive terminal (1411) and a negative terminal (1412). The two AC buses (1510 and 1520) each include an AC terminal (1511;1521).

This embodiment can be known as a Full Bridge IPB, and can be preferred when targeting a range of applications including but not exclusive to bidirectional single-phase power conversion. Switching device subsystem (1340) takes the form of semiconductor transistor circuits (“FETs”) (1341;1342;1343; 1344), such as GaN Systems GS66508B. The FETs are Wide Band Gap switching semiconductor transistors, typically Gallium Nitride (GaN) or Silicon Carbide (SiC) field-effect transistors or a member of a related semiconductor family, as well as alternate or future versions as can be appreciated by one having skill in the art. Each transistor is capable of electrically switching at high frequencies (typically around one MHz), withstanding high voltages (typically up to 650V DC), and conducting high currents (typically 30-60A). In addition, each FET in this embodiment is thermally coupled to an externally accessible insulated metal substrate (IMS) layer (1350), which can greatly increase maximal thermal dissipation in comparison to other thermal management methods and thus can increase switching efficiency.

The DC bus (1410) enclosed in this embodiment of the IPB takes the form of a pair of parallel conductive rails. AC bus A (1510) and AC bus B (1520) (commonly known as “switching nodes”) enclosed in the IPB are each a single conductive rail. Each of the aforementioned AC or DC rails is externally accessible via a termination (for example, a 0.25 inch Quick Disconnect terminal)—positive DC terminal (1411) and negative DC terminal (1412) terminate DC bus (1410) appropriately, while AC terminals A and B (1511;1521) terminate their respective AC buses A and B (1510;1520).

In this embodiment, the four transistors are arranged in a Full Bridge configuration: two parallel Half Bridges, where each Half Bridge comprises a pair of FETs. This configuration lends its name to the embodiment. FETs (1341) and (1342) are the “top” FET and the “bottom” FET of Half Bridge A, while FETs (1343) and (1344) are the “top” and “bottom” FETs of Half Bridge B. The Half Bridges are coupled in the following manner:
the drain of FETs (1341) and (1343) are each coupled to the positive DC terminal (1411);
the source of FETS (1342) and (1344) are each coupled to the negative DC terminal (1412);
the source of FET (1341) is coupled to AC bus A (1510) and to the drain of FET (1342), forming Half Bridge A such that AC bus A is referred to as switching node A; and
the source of FET (1343) is coupled to AC bus B (1520) and to the drain of FET (1344), forming Half Bridge B such that AC bus B is referred to as switching node B.

A digital signal processing subsystem (1210) is, in this embodiment, digital signal processing circuit (“DSP”) (1211) comprising a signal processing microcontroller such as Texas Instruments TMS320F280049 or Texas Instruments TMS320F28335. The primary role of the signal processing subsystem in an IPB is to generate pulse-width modulated (“PWM”) signals and input/output (I/O) signals, among others, as configured by a software framework typically associated with the signal processor or signal processors therein.

The PWM signals are directly coupled to the Gate Control mechanism of the IPB, configured by the software framework to act as timekeepers for the FETs. While the I/O signals are multifaceted in use and nature, a high density connector (“HDC”) (1220), such as Panasonic AXK580147YG, typically directly couples them to an external feedback mechanism configured to interface with an IPB's signal processing microcontroller.

Gate driver circuit A (1331) and gate driver circuit B (1332) are used to actively control the states of the FETs, forming the Gate Control mechanism of the Full Bridge IPB as gate driver subsystem (1330). In this embodiment, each gate driver circuit comprises a commercially available isolated gate driver component (for example, Skyworks Si8273AB-IM1), and can be referred to as an isolated gate driver circuit (“IGD”). Each IGD is configured to safely switch one Half Bridge-IGD A (1331) controls Half Bridge A, and IGD B (1332) controls Half Bridge B.

An isolated gate driver component electrically isolates the electrical circuit of the source of a PWM (in this embodiment, the DSP) and couples the isolated PWM to the gate of the semiconductor transistors. This effectively prevents undesirable and unpredictable secondary or tertiary electrical interaction between the power switch and gate control logic, and is the preferred choice for most designs. Such undesirable interactions, if not prevented, can lead to consequences ranging from distortion of output waveforms to catastrophic failure of the switching transistors. If necessary, an alternate configuration of the IPB is to use non-isolated gate driver circuits comprising non-isolated gate driver components (such as Onsemi NCP51820), in combination with discrete digital isolator components (such as Maxim Integrated MAX12934), the combination of which would replace IGD A and IGD B in an embodiment requiring gate driver circuits with specific functions not offered by typical isolated gate driver components.

In the Full Bridge IPB, logic power subsystem (1310) is a logic power circuit (“LP”) (1311) which typically comprises a voltage regulator (such as Renesas RAA223021) directly powered by the DC bus and producing a desired low voltage DC output (12V) anywhere between 5V and 18V, as determined by system requirements, which is capable of providing up to 7 W of DC power for the purpose of energizing the IGDs, among other purposes. The LP's low voltage DC output can additionally be coupled to the HDC, and can thus be used for a number of auxiliary tasks which require low-voltage input, including but not limited to providing power to a second voltage regulator which can power the DSP.

A critical failure mode of the IPB is the race condition during start up between the transient voltage of the DC bus and the transient low voltage DC output of the LP (1311). Improperly applying the DC bus before the LP is fully energized and its output is fully stabilized can lead to insufficient gate drive signals for any random combination of the FETs (1341; 1342; 1343;1344), leading to the potential destruction of any of the FETs at random. In this embodiment, power failsafe subsystem (1320) comprises a power failsafe circuit (“FSL”) (1321), which defeats this adverse condition by disabling IGD A and IGD B, then monitoring the transient voltage of the DC bus and the transient low voltage DC output of the LP, each through a separate voltage divider. When each of the transient voltages reach steady state and are stable, FSL asserts the control signal which enables IGD A and IGD B to operate, thus preventing untimely application of the DC bus and permitting failsafe operation of the power switching devices.

The Full Bridge IPB's mode of operation begins with the DSP pre-loaded with a required program through a user interface (“UI”) connector (1240) such as EDAC 690-W05-290-483. In an embodiment which uses a Universal Serial Bus (USB) connector, this process is accomplished through the user's computer. In an embodiment which uses Texas Instruments' TMS320F280049 or a similar Texas Instruments signal processing microcontroller, this process is additionally accomplished through the use of their C2000Ware Software Development Kit, streamlined through their open-source CCSTUDIO IDE. In an embodiment which uses a different connector or a different microcontroller, the process may differ.

In this embodiment, the UI connector (1240) is coupled to the DSP's I/O signals via communication interface (“CI”) (1230), comprising signal isolator (1231) such as Analog Devices ADUM4160. In some embodiments, the communication interface may additionally comprise a protocol converter circuit (1232), which might use a dedicated component (such as FTDI FT2232H) to intercept input to the IPB from the UI connector through the signal isolator, interpret the isolated input as JTAG signals, and couple those signals to the DSP.

The combination of the power system (1300) and the heavily developed control system (1200) enable the virtually autonomous operation of the IPB once correctly configured, enabling a host of self-contained high voltage, high current, high frequency switching applications requiring only low power and low-level feedback, and using signals of minimal complexity.

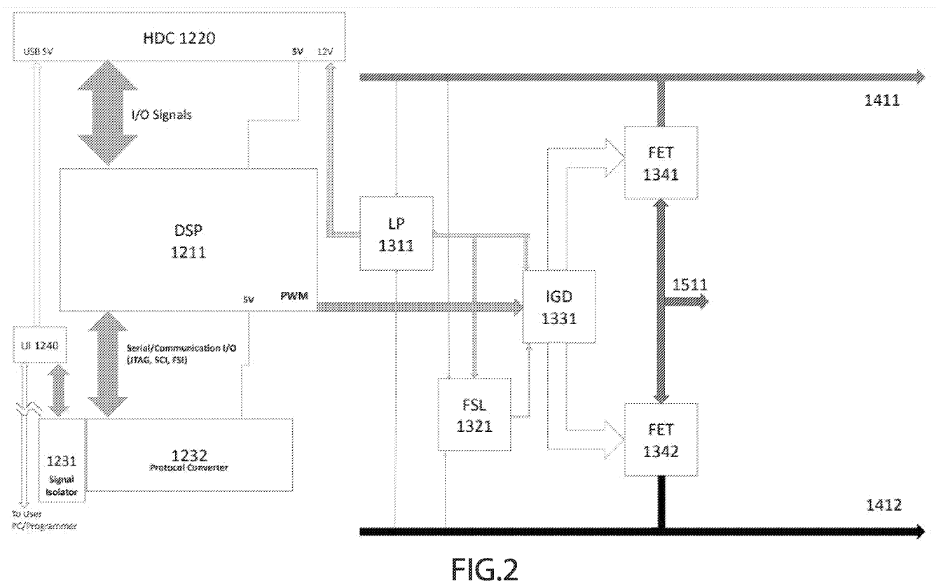

FIG. 2 shows a schematic block diagram illustrating a Half Bridge IPB according to a second illustrated embodiment. In the second embodiment, the IPB comprises in a sealed hardware block a case (1100) with an outer shell and internal material, and a power system (1300) comprising two high frequency, high power semiconductor transistors (1341;1342), a gate driver circuit (1331), a logic power circuit (1311), a power failsafe circuit (1321), and an insulated metal substrate layer (1350). The IPB further comprises a control system (1200) comprising a digital signal processing circuit (1211), a communication interface (1230) with integrated signal isolator (1231) and protocol converter circuit (1232), a user interface connector (1240), and a high-density connector (1220). The IPB further includes a DC bus (1410) with a positive terminal (1411) and a negative terminal (1412), and an AC bus (1510) with an AC terminal (1511).

This embodiment, which can be known as a Half Bridge IPB, shares a great deal of structural similarity with the Full Bridge IPB of FIG. 1. It can be preferred when a single application which utilizes a single Half Bridge is targeted, such as a single-phase inverter or a high-frequency transformer for a DC-DC converter, or for other preferences not detailed. In the Half Bridge IPB, a switching device subsystem (1340) takes the form of FETs (1341) and (1342), thermally coupled to an IMS layer (1350). The two transistors are arranged in a Half Bridge, wherein IGD (1331) drives FETs (1341) and (1342) as the “top” FET and “bottom” FET of the Half Bridge, and AC bus (1510) serves as the switching node. LP (1311) provides logic power to the IGD, and FSL (1321) permits its failsafe operation. Positive DC terminal (1411) and negative DC terminal (1412) terminate DC bus (1410) appropriately, while AC terminal (1511) terminates the AC bus.

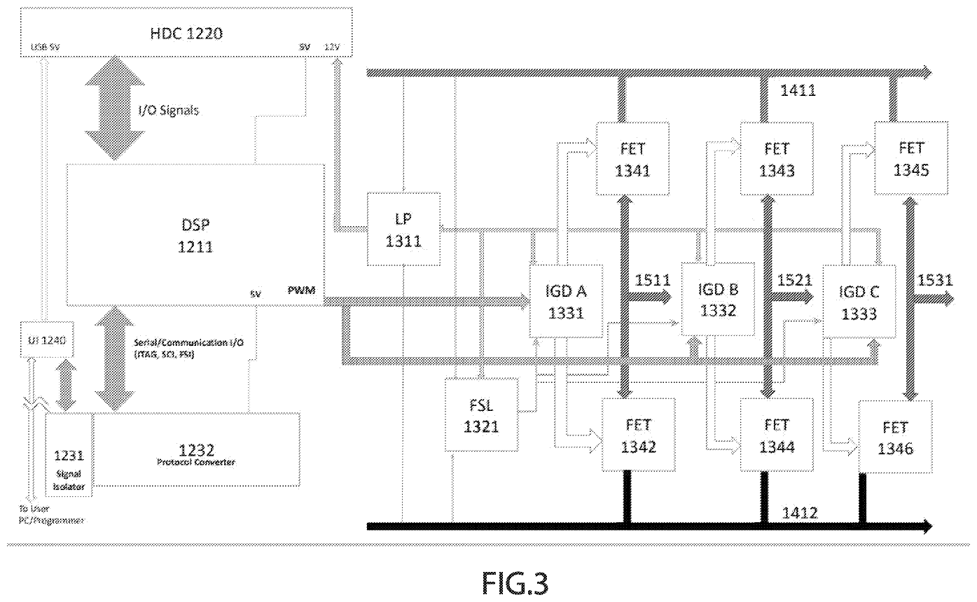

FIG. 3 shows a schematic block diagram illustrating a Three Phase IPB, in accordance with a third illustrated embodiment. In the third embodiment, the IPB comprises functional elements as a single sealed hardware block including a case (1100) with an outer shell and internal material, and a power system (1300) comprising six high frequency, high power semiconductor transistors (1341-1346), three gate driver circuits (1331; 1332; 1333), a logic power circuit (1311), a power failsafe circuit (1321), and an insulated metal substrate layer (1350). The IPB further comprises a control system (1200) comprising a digital signal processing circuit (1211), a communication interface (1230) with integrated signal isolator (1231) and protocol converter circuit (1232), a user interface connector (1240), and a high-density connector (1220). Additionally, the IPB comprises a DC bus (1410) with a positive terminal (1411) and a negative terminal (1412), and three AC buses (1510; 1520; 1530) each with an AC terminal (1511; 1521; 1531).

This embodiment, which can be known as a Three Phase IPB, is preferred when a single three-phase application is targeted. It is evident from this embodiment that an IPB's power system can comprise a number of FETs limited only by mechanical constraints and the capabilities of the signal processing subsystem. A switching device subsystem (1340) takes the form of multiple FETs (1341; 1342; 1343; 1344; 1345; 1346), each thermally coupled to an IMS layer (1350). The six transistors are arranged in three Half Bridges, wherein IGD A (1331) drives FETs (1341) and (1342) as Half Bridge A, IGD B (1332) drives FETS (1343) and (1344) as Half Bridge B, and IGD B (1333) drives FETS (1345) and (1346) as Half Bridge C. AC bus A (1510) serves as switching node A, AC bus B (1520) serves as switching node B, and AC bus C (1530) serves as switching node C. LP (1311) provides logic power to the IGDs, and FSL (1321) permits their failsafe operation. Positive DC terminal (1411) and negative DC terminal (1412) terminate DC bus (1410) appropriately. AC terminal A (1511) terminates AC bus A, AC terminal B (1512) terminates AC bus B, and AC terminal C (1513) terminates AC bus C.

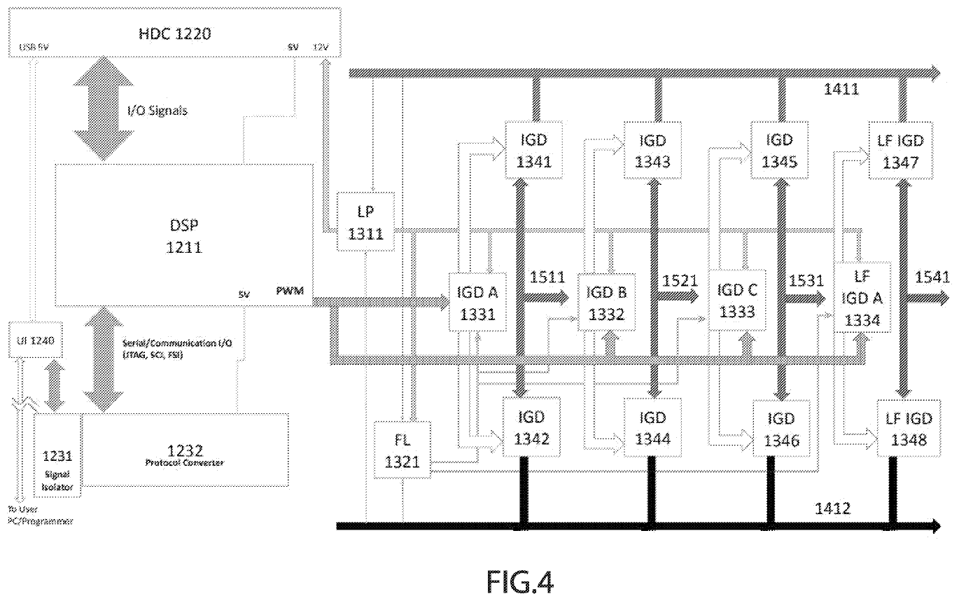

FIG. 4 shows a schematic block diagram illustrating a Three Phase+Half Bridge IPB, in accordance with a fourth illustrated embodiment. In the fourth embodiment the IPB comprises the following functional elements as a single sealed hardware block:
a case (1100) with an outer shell and internal material;
a power system (1300) comprising six high frequency, high power semiconductor transistors (1341-1346), two low frequency, high power semiconductor transistors (1347;1348), three gate driver circuits (1331; 1332; 1333), a low frequency gate driver circuit (1334), a logic power circuit (1311), a power failsafe circuit (1321), and an insulated metal substrate layer (1350);
a control system (1200) comprising a digital signal processing circuit (1211), a communication interface (1230) with integrated signal isolator (1231) and protocol converter circuit (1232), a user interface connector (1240), and a high-density connector (1220);
a DC bus (1410) with a positive terminal (1411) and a negative terminal (1412); and
four AC buses (1510; 1520; 1530; 1540) each with an AC terminal (1511; 1521; 1531; 1541).

This embodiment, which can be known as a Three Phase+Low Frequency (3PLF) IPB, is preferred when a bidirectional three-phase application is targeted. It is evident from this embodiment that an IPB can utilize one or more high-frequency switched pairs alongside one or more low-frequency switched pairs, or any combination therein, to achieve scaling bidirectional operation. The switching device subsystem (1340) takes the form of multiple FETs (1341; 1342; 1343; 1344; 1345; 1346), as well as an additional pair of low frequency switching device circuits (“LF FETs”) (1347; 1348) such as STMicroelectronics STY145N65M5. Each FET and LF FET being thermally coupled to IMS layer (1350). The eight transistors are arranged in four Half Bridges, wherein IGD (1331) drives FETs (1341) and (1342) as Half Bridge A, IGD (1332) drives FETs (1343) and (1344) as Half Bridge B, and IGD (1333) drives FETS (1345) and (1346) as Half Bridge C. AC bus A (1510) serves as switching node A, AC bus B (1520) serves as switching node B, and AC bus C (1530) serves as switching node C. Positive DC terminal (1411) and negative DC terminal (1412) terminate DC bus (1410) appropriately. AC terminal A (1511) terminates AC bus A, AC terminal B (1512) terminates AC bus B, and AC terminal C (1513) terminates AC bus C.

In the 3PLF IPB, LF FETs (1347; 1348) are driven by LF IGD (1334) as the LF Half Bridge, and LF AC bus (1540) serves as the LF switching node. The LF IGD comprises a specialized gate driver component (such as Texas Instruments UCC27714D), configured to operate the LF FETs at a common utility frequency (such as 50 Hz, 60 Hz, or 400 Hz) The LF IGD may also comprise a discrete digital isolator component. LP (1311) can provide logic power to the IGDs and LF IGDs, and FSL (1321) permits their failsafe operation. LF AC terminal (1514) terminates the LF AC bus.

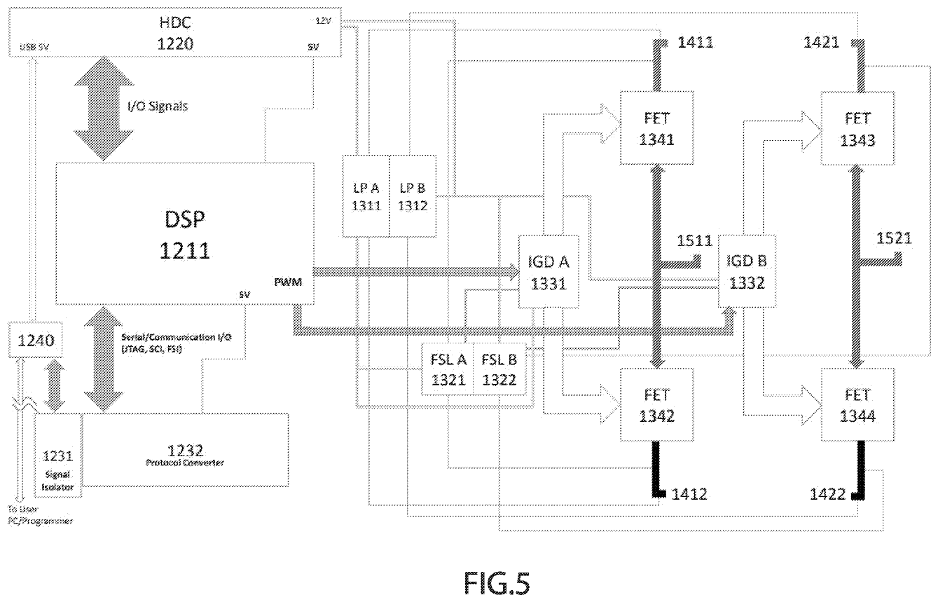

FIG. 5 shows a schematic block diagram illustrating a Dual Half Bridge IPB, in accordance with a fifth illustrated embodiment. In the fifth embodiment, the IPB comprises the following functional elements as a single sealed hardware block:
a case (1100) with an outer shell and internal material;
a power system (1300) comprising four high frequency, high power semiconductor transistors (1341-1344), two gate driver circuits (1331; 1332), two logic power circuits (1311; 1312), two power failsafe circuits (1321; 1322), and an insulated metal substrate layer (1350);
a control system (1200) comprising a digital signal processing circuit (1211), a communication interface (1230) with integrated signal isolator (1231) and protocol converter circuit (1232), a user interface connector (1240), and a high-density connector (1220);
two DC buses (1410; 1420), each with a positive terminal (1411; 1421) and a negative terminal (1412; 1422); and
two AC buses (1510; 1520) each with an AC terminal (1511; 1521).

This embodiment, which can be known as a Dual Half Bridge IPB, is similar to the Full Bridge IPB but features a split DC bus. This can be preferred in a range of situations including but not exclusive to the simultaneous operation of two Half Bridge applications. It is evident from this embodiment that the buses can be isolated from each other, and that a single IPB can thus operate a number of discrete applications limited only by mechanical constraints and the capabilities of the signal processing subsystem. The switching device subsystem (1340) takes the form of multiple FETs (1341; 1342; 1343; 1344), each thermally coupled to IMS layer (1350). The four transistors are arranged in two isolated Half Bridges, wherein IGD A (1331) drives FETs (1341; 1342) as Half Bridge A, and IGD B (1332) drives FETS (1343; 1344) as Half Bridge B. AC bus A (1510) serves as switching node A, and AC bus B (1520) serves as switching node B.

LP A (1311) draws power exclusively from DC bus A (1410) and provides logic power to IGD A, while LP B (1312) draws its power from DC bus B (1420) and provides logic power to IGD B. FSL A (1321) permits failsafe operation of IGD A by monitoring the transient voltage of DC bus A and the transient low voltage DC output of LP A, while FSL B (1322) permits failsafe operation of IGD B monitoring DC bus B and LP B. Positive DC terminal A (1411) and negative DC terminal A (1412) terminate DC bus A (1410), while positive DC terminal B (1421) and negative DC terminal B (1422) terminate DC bus B (1420) appropriately. AC terminal A (1511) terminates AC bus A, and AC terminal B (1512) terminates AC bus B.

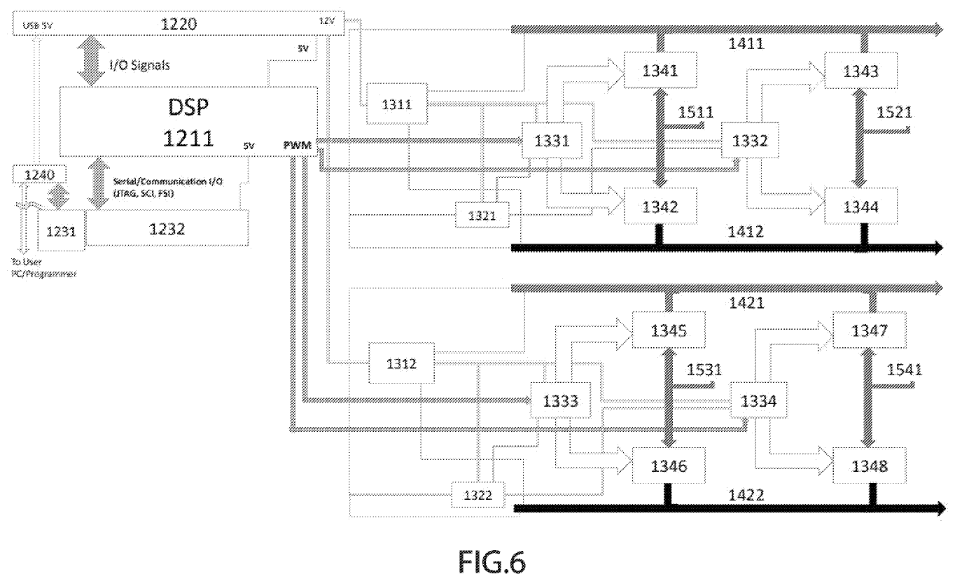

FIG. 6 shows a schematic block diagram illustrating a Dual Full Bridge IPB, in accordance with a sixth illustrated embodiment. In the sixth embodiment, the IPB comprises the following functional elements as a single sealed hardware block:
a case (1100) with an outer shell and internal material;
a power system (1300) comprising eight high frequency, high power semiconductor transistors (1341-1348), four gate driver circuits (1331-1334), two logic power circuits (1311-1312), two power failsafe circuits (1321-1322), and an insulated metal substrate layer (1350);
a control system (1200) comprising a digital signal processing circuit (1211), a communication interface (1230) with integrated signal isolator (1231) and protocol converter circuit (1232), a user interface connector (1240), and a high-density connector (1220);
two DC buses (1410 and 1420), each with a positive terminal (1411, 1421) and a negative terminal (1412, 1422); and
four AC buses (1510, 1520, 1530, and 1540) each with an AC terminal (1511, 1521, 1531, and 1541).

This embodiment, which can be known as a Dual Full Bridge IPB, is similar to the Dual Half Bridge IPB but features two Full Bridges rather than two Half Bridges. The Dual Full Bridge IPB can be preferred in a range of situations including but not exclusive to the simultaneous operation of four parallel single-phase applications, two Full Bridge applications, or the combined operation of a single Dual Active Bridge. It is evident from this embodiment that an IPB can comprise a combination of one or more isolated DC buses and one or more combined DC buses, and any combination thereof, and thus can be constructed and configured operate one or more discrete multiphase or bidirectional applications, or any combination therein. The switching device subsystem (1340) takes the form of FETs (1341-1348), each thermally coupled to IMS layer (1350).

The four transistors are arranged in two isolated Full Bridges. IGD A (1331) drives FETs (1341) and (1342) as Half Bridge A. IGD B (1332) drives FETS (1343) and (1344) as Half Bridge B. Half Bridges A and B together form Full Bridge AB.

IGD C (1333) drives FETs (1345) and (1346) as Half Bridge C, while IGD D (1334) drives FETS (1347) and (1348) as Half Bridge D. Half Bridges C and D form Full Bridge CD.

AC bus A (1510) serves as switching node A, AC bus B (1520) serves as switching node B, AC bus C (1530) serves as switching node C, and AC bus D (1540) serves as switching node D.

LP AB (1311) draws power exclusively from DC bus AB (1410) and provides logic power to IGD A and IGD B. LP CD (1312) draws its power from DC bus CD (1420) and provides logic power to IGD C and IGD D. FSL AB (1321) permits failsafe operation of IGD A and IGD B by monitoring the transient voltage of DC bus AB and the transient low voltage DC output of LP AB. Similarly, FSL CD (1322) permits failsafe operation of IGD C and IGD D by monitoring DC bus CD and LP CD. Positive DC terminal AB (1411) and negative DC terminal AB (1412) terminate DC bus AB (1410), while positive DC terminal CD (1421) and negative DC terminal CD (1422) terminate DC bus CD (1420) appropriately. AC terminal A (1511) terminates AC bus A, AC terminal B (1521) terminates AC bus B, AC terminal C (1531) terminates AC bus C, and AC terminal D (1541) terminates AC bus D.

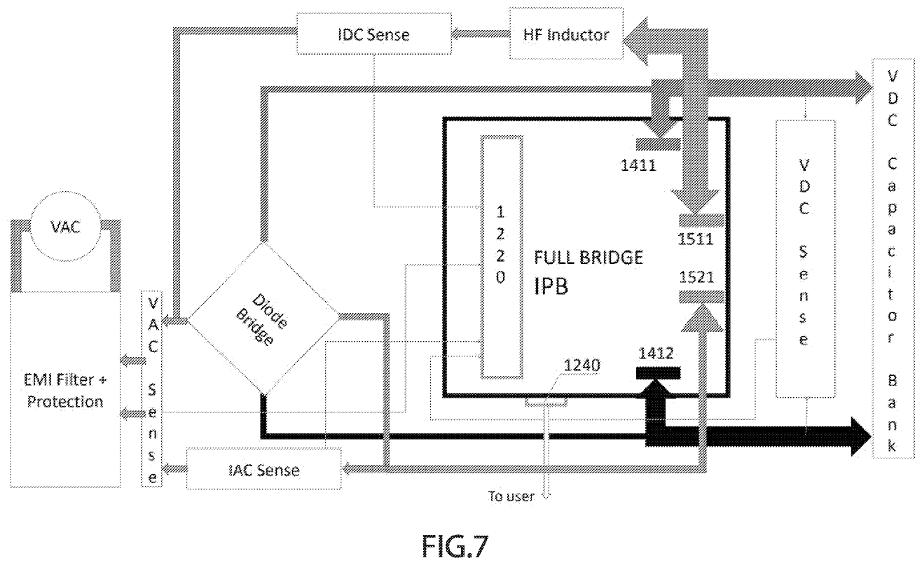

FIG. 7 shows an example power conversion solution utilizing a Full Bridge IPB as the core of an AC to DC Power Factor Correction (PFC) configuration, or by loading a different program, instead utilizing the same hardware with its interconnections as a DC to AC Inverter.

When the IPB is configured as the core of a PFC, Grid Outlet VAC is used as the incoming AC voltage source. When turned ON, the applied AC voltage begins charging the 880 uF 450V VDC Capacitor Bank (for example, 4×220 uF 450V capacitors) via the 800V 25A Diode Bridge (such as Shindengen D25XB60-7000). When the DC voltage across the VDC Capacitor Bank reaches adequate voltage threshold, the IPB activates FETs (1341) and (1342) to function as a low frequency half bridge, bypassing the Diode Bridge to reduce power dissipation. The combination of the HF Inductor (such as GCI Technologies G164005LF), AC bus A (1511), and the VDC Capacitor Bank can now function as a conventional Boost Converter. Voltage Sensors 400V/1.94V VDC Sense and 140:1 Resistive Divider VAC Sense, and Current Sensors 132 mV/A IDC Sense (such as Allegro MicroSystems ACS722LLCTR-10AB-T) and 37 mV/A IAC Sense (such as Allegro MicroSystems ACS716KLATR-12CB-NL-T) enable the IPB to generate AC current in phase with incoming AC voltage, thus achieving Unity Power Factor Correction with typical efficiency of 98%.

Alternatively, when the software configures the IPB as an inverter and the VDC Capacitor Bank is charged through a DC source such as a battery or solar panels, this same solution with the same set of hardware instead generates utility frequency AC current with the combination of the HF Inductor and AC bus A (1511), which is routed to maintain correct low frequency polarity by AC bus B (1521). This can be used as an independent AC voltage source, or can be used to supply current to an AC grid as the AC voltage source, thus achieving fully reprogrammable bidirectional operation.

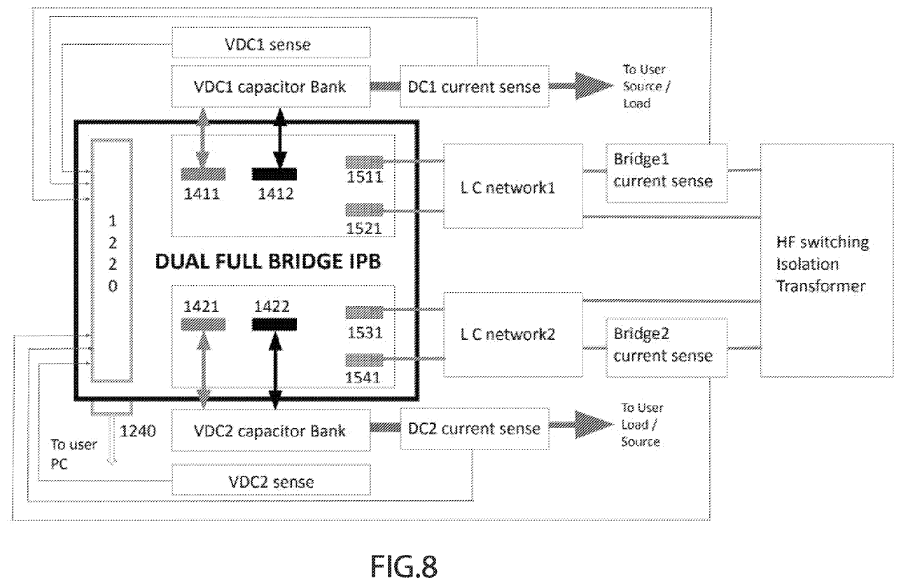

FIG. 8 shows a second power solution, utilizing the Dual Full Bridge IPB of FIG. 6 as the core of a bidirectional Dual Active Bridge DC-DC converter (such as Texas Instruments Reference Design TIDA-010054). The dual active bridge circuit is bidirectional, and operates in a given direction by applying the input DC voltage to the primary winding of the transformer and switching the voltage on and off at the primary winding, thereby inducing a corresponding voltage in the secondary winding and regulating the voltage across the load. The use of the transformer provides electrical isolation and protection, and the control circuit enables efficient voltage conversion and regulation. The use of a correctly configured Dual Full Bridge IPB in such a topology bestows numerous advantages, including but not limited to the fully reprogrammable bidirectional operation mentioned in FIG. 7.

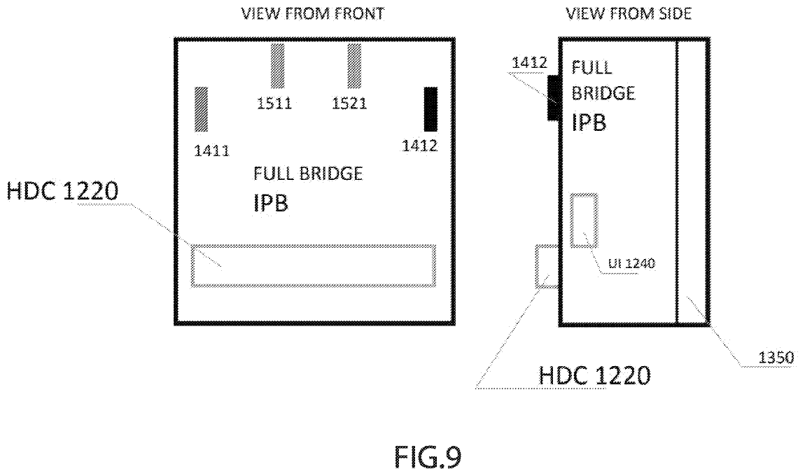

FIG. 9 shows front and side views of Intelligent Power Block IPB. Depicted are the approximate physical positions of positive DC terminal (1411) and negative DC terminal (1412). Also depicted are AC terminals (1511) and (1521), the HDC (1220). and UI connector (1240). FETs (1341-1344) are thermally coupled to IMS layer (1350) for the purpose of dissipating heat. The Full Bridge IPB's size can be less than 27 cubic inches.

What is claimed is:

1. A system for digital power conversion (1000), comprising:
a case (1100) comprising an insulating outer shell and an insulating internal material;
a control system (1200) housed in the case,
wherein the control system is configured by a software framework to output pulse-width modulated (PWM) signals and input/output (I/O) signals;
a power system (1300) housed in the case,
wherein the power system is configured to receive and operate in accordance with the PWM signals;
a DC bus system (1400) housed in the case and electrically coupled to the power system,
wherein the DC bus system comprises one or more DC buses, each individually comprising a positive DC bus and a negative DC bus, and
wherein the positive DC bus and the negative DC bus of each of the one or more DC buses are each externally accessible via a corresponding pair of DC terminals comprising a positive DC terminal and a negative DC terminal; and
an AC bus system (1500) housed in the case and electrically coupled to the power system, wherein the AC bus system comprises one or more AC buses, and
wherein each of the one or more AC buses is externally accessible via an AC terminal;

2. The system for digital power conversion of claim 1, wherein the case further comprises a conductive internal lining disposed between the insulating outer shell and the insulating internal material, configured to act as a Faraday cage.

3. The system for digital power conversion of claim 1, wherein the control system comprises a digital signal processing subsystem (1210) comprising one or more digital signal processing circuits, wherein the digital signal processing subsystem is configured to generate and transmit the PWM signals and the I/O signals, the I/O signals comprise serial/communication I/O signals, and wherein the control system further comprises an externally accessible high density connector (1220) electrically coupled to at least one of the I/O signals.

4. The system for digital power conversion of claim 1, wherein the control system further comprises a communication interface subsystem (1230) and one or more externally accessible user interface connectors (1240), the communication interface subsystem comprises a signal isolator (1231), and wherein the communication interface subsystem electrically couples the serial/communication I/O signals to the one or more externally accessible user interface connectors.

5. The system for digital power conversion of claim 1, wherein the power system comprises:
a logic power subsystem (1310) comprising one or more logic power circuits, electrically coupled to the DC bus system;
a power failsafe subsystem (1320), electrically coupled to the logic power subsystem and comprising sensing elements;
a gate driver subsystem (1330) comprising one or more gate driver circuits, each gate driver circuit being electrically coupled to the power failsafe subsystem and to the PWM signals; and
a switching device subsystem (1340) comprising one or more semiconductor transistor circuits, each semiconductor transistor circuit being electrically coupled to the gate driver subsystem, and the switching device subsystem being electrically coupled to the DC bus system or the AC bus system.

6. The system for digital power conversion of claim 5, wherein the power system further comprises an insulated metal substrate layer (1350) bonded to the power system, and
wherein the insulated metal substrate layer is externally accessible and is thermally coupled to at least one of the one or more semiconductor transistors.
